(19) United States
(12) Patent Application Publication
(10) Pub. No.: US 2016/0372424 A1
(43) Pub. Date: Dec. 22, 2016

(54) LOW-WARPAGE SEMICONDUCTOR SUBSTRATE AND METHOD FOR PREPARING SAME

(71) Applicant: Shanghai Simgui Tehcnology Co., Ltd., Shanghai (CN)

(72) Inventors: Fei YE, Shanghai (CN); Qianzhi MA, Shanghai (CN); Meng CHEN, Shanghai (CN); Guoxing CHEN, Shanghai (CN)

(21) Appl. No.: 15/162,136

(22) Filed: May 23, 2016

Related U.S. Application Data
(63) Continuation of application No. PCT/CN2014/089980, filed on Oct. 31, 2014.

(30) Foreign Application Priority Data
Nov. 22, 2013 (CN) 201310591315.3

(51) Int. Cl. H01L 23/00; H01L 21/84; H01L 21/762; H01L 27/12

(52) U.S. Cl. CPC H01L 23/562; H01L 27/1203; H01L 21/84; H01L 21/76251

(57) ABSTRACT

Disclosed are a low-warpage semiconductor substrate and a method for preparing the same. The method includes: providing a first substrate and a second substrate, the first substrate comprising a first surface and a second surface which are opposite to each other, the first surface being provided with a first insulating layer. A second insulating layer is dispose on the second surface. A support layer is disposed on the second substrate. An oxidation layer is arranged on a surface of the support layer and a device layer is arranged on a surface of the oxidation layer. The method further includes bonding the first substrate and the second substrate; and forming a passivation layer on a surface of the second insulating layer by epitaxy, where the second insulating layer and the passivation layer are configured to adjust warpage of the semiconductor substrate.

The present application is a continuation of International Application No. PCT/CN2014/089980, filed on Oct. 31, 2014, which is based upon and claims priority to Chinese Patent Application No. 201310591315.3, filed on Nov. 22, 2013, the entire contents of which are incorporated herein by reference.

### TECHNICAL FIELD

The present disclosure relates to methods for preparing silicon substrates on insulators, and in particular, relates to a low-warpage semiconductor substrate and a method for preparing the same.

### BACKGROUND

During the preparation process of a silicon-on-insulator (SOI) wafer, an oxidation layer on a surface of a device layer needs to be corroded. In addition, an insulating layer supporting a back side of a substrate is removed during the process of corrosion the oxidation layer, which results in that warpage of a silicon wafer is great. As illustrated in FIG. 1A, a first surface of a support substrate 100 is provided with a device layer 110 and an oxidation layer 120 located above the device layer 110; a second surface of the support substrate 100 opposite to the first surface thereof is provided with an insulating layer 130; when the oxidation layer 120 is removed by means of corrosion, the corrosion liquid sputters or flows, which may cause the insulating layer 130 to be removed because of the corrosion. As a result, the warpage of the semiconductor substrate is great. FIG. 1B is a transmission electron microscope diagram of a bonded SOI wafer in the related art. It can be seen from FIG. 1B that an inclination angle of the semiconductor substrate is great after the oxidation layer 120 is removed, which indicates that the warpage of the semiconductor substrate is great. A great warpage of the semiconductor substrate may result in such circumstances as component failure, and occurrence of fragments during the preparation process of the semiconductor substrate, which causes yield loss. Therefore, a user desires a low-warpage semiconductor substrate.

### SUMMARY

A technical problem to be solved in the present disclosure is to provide a low-warpage semiconductor substrate and a preparation method thereof. This method is capable of reducing warpage of a wafer.

In a first aspect, the present disclosure provides a low-warpage semiconductor substrate. The semiconductor substrate includes: a support substrate including a first surface and a second surface which are opposite to each other; a first insulating layer, arranged on a first surface of the support substrate; and a device layer, arranged on a surface of the first insulating layer; where the semiconductor substrate further includes a second insulating layer and a passivation layer, the second insulating layer being arranged on a second surface of the support substrate, the passivation layer being arranged on a surface of the second insulating layer, and the second insulating layer and the passivation layer being configured to adjust warpage of the semiconductor substrate.

In a second aspect, the present disclosure further provides a method for preparing a low-warpage semiconductor substrate. The method includes: providing a first substrate and a second substrate, the first substrate including a first surface and a second surface which are opposite to each other, disposing a first insulating layer on the first surface, disposing a second insulating layer on the second surface. The second substrate includes a support layer, an oxidation layer arranged on a surface of the support layer and a device layer arranged on a surface of the oxidation layer. The method further includes: bonding the first substrate and the second substrate by using the device layer and the first insulating layer as an intermediate layer; and forming a passivation layer on a surface of the second insulating layer by epitaxy, where the second insulating layer and the passivation layer are configured to adjust warpage of the semiconductor substrate.

The advantages of the present disclosure lie in that: a passivation layer is arranged on a surface of an insulating layer, and is capable of preventing the insulating layer from corrosion, such that warpage of a crystal plate is effectively reduced, and may be adjusted according to the thicknesses of the insulating layer and the passivation layer.

### BRIEF DESCRIPTION OF THE DRAWINGS

FIG. 1A is a schematic process diagram of removing an oxidation layer by means of corrosion during the preparation of a SOI wafer in the related art;

FIG. 1B is a transmission electron microscope of a bonded SOI wafer in the related art;

FIG. 2 is a schematic diagram of steps of a method for preparing a low-warpage semiconductor substrate according to one or more embodiments of the present disclosure;

FIG. 3A to FIG. 3E are schematic diagrams of an implementation process according to one or more embodiments of the present disclosure;

FIG. 4 is a transmission electron microscope of a semiconductor substrate prepared by using the method according to the present disclosure; and

FIG. 5 is a comparison of warpage of a semiconductor substrate prepared by using the method of the present disclosure, and warpage of a semiconductor substrate prepared by using a conventional method in the related art.

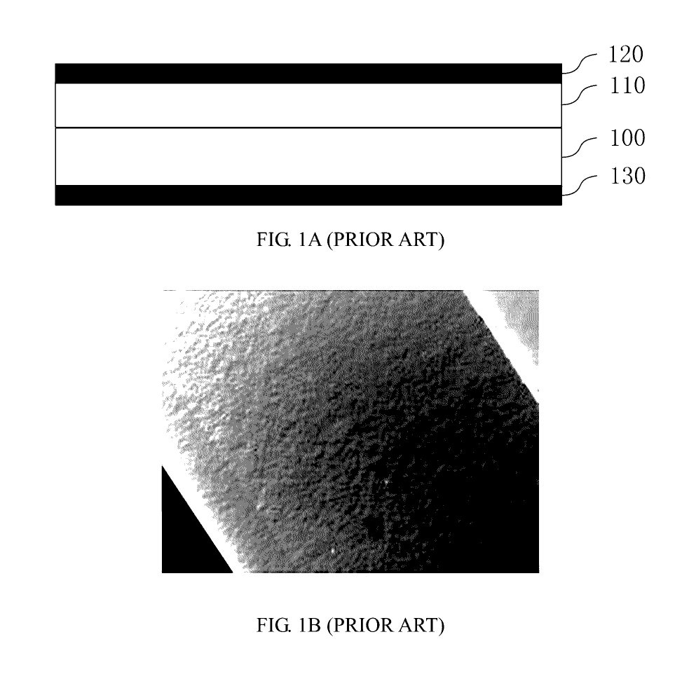

### DETAILED DESCRIPTION

Embodiments illustrating a low-warpage semiconductor substrate and a method for preparing the same according to the present disclosure are described in detail with reference to the accompanying drawings.

The terminology used in the present disclosure is for the purpose of describing exemplary embodiments only and is not intended to limit the present disclosure. As used in the present disclosure and the appended claims, the singular forms “a,” “an” and “the” are intended to include the plural forms as well, unless the context clearly indicates otherwise. It shall also be understood that the terms “or” and “and/or” used herein are intended to signify and include any or all possible combinations of one or more of the associated listed items, unless the context clearly indicates otherwise.

It shall be understood that, although the terms “first,” “second,” “third,” etc. may include used herein to describe various information, the information should not be limited by these terms. These terms are only used to distinguish one category of information from another. For example, without departing from the scope of the present disclosure, first information may include termed as second information; and similarly, second information may also be termed as first information. As used herein, the term “if” may include understood to mean “when” or “upon” or “in response to” depending on the context.

Reference throughout this specification to “one embodiment,” “an embodiment,” “exemplary embodiment,” or the like in the singular or plural means that one or more particular features, structures, or characteristics described in connection with an embodiment is included in at least one embodiment of the present disclosure. Thus, the appearances of the phrases “in one embodiment” or “in an embodiment,” “in an exemplary embodiment,” or the like in the singular or plural in various places throughout this specification are not necessarily all referring to the same embodiment. Furthermore, the particular features, structures, or characteristics in one or more embodiments may include combined in any suitable manner.

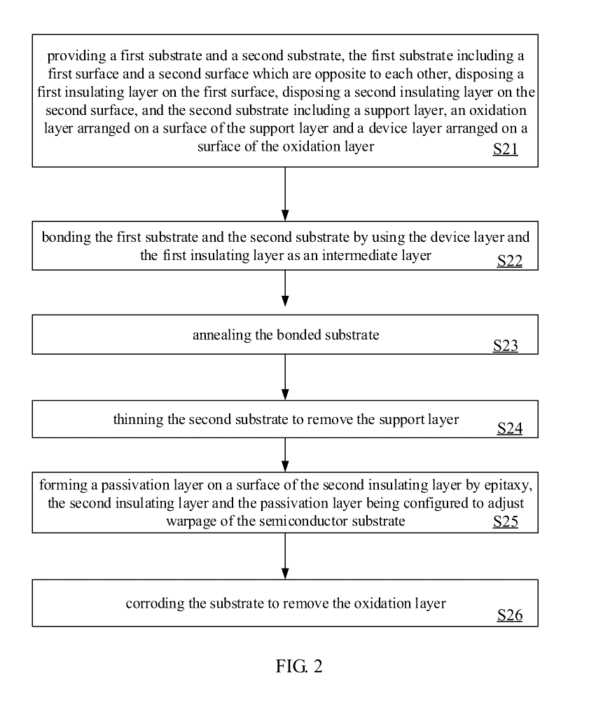

FIG. 2 is a schematic diagram of steps of a method for preparing a low-warpage semiconductor substrate according to an embodiment of the present disclosure. The method includes the following steps: step S21, providing a first substrate and a second substrate, the first substrate including a first surface and a second surface which are opposite to each other, the first surface being provided with a first insulating layer, the second surface being provided with a second insulating layer, and the second substrate including a support layer, an oxidation layer arranged on a surface of the support layer and a device layer arranged on a surface of the oxidation layer; step S22, bonding the first substrate and the second substrate by using the device layer and the first insulating layer as an intermediate layer; step S23, annealing the bonded substrate; step S24, thinning the second substrate to remove the support layer; step S25, forming a passivation layer on a surface of the second insulating layer by epitaxy, the second insulating layer and the passivation layer being configured to adjust warpage of the semiconductor substrate; step S26, corroding the substrate to remove the oxidation layer.

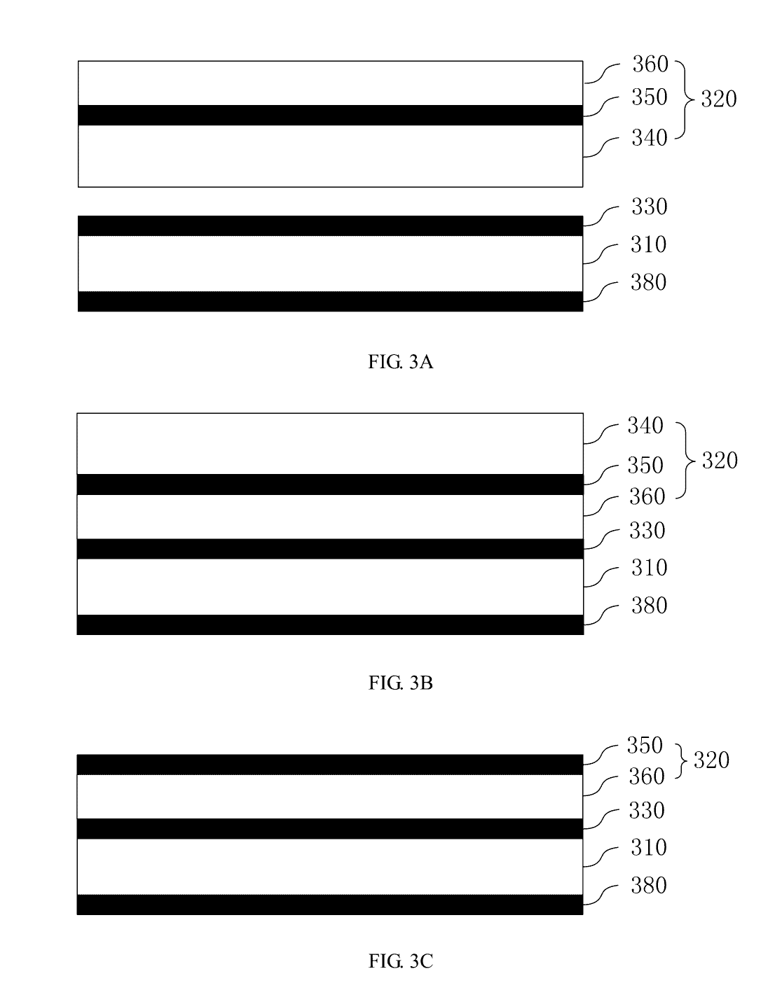

As illustrated in FIG. 3A, with reference to step S21, a first substrate 310 and a second substrate 320 are provided, wherein the first substrate 310 includes a first surface and a second surface which are opposite to each other, the first surface being provided with a first insulating layer 330, the second surface being provided with a second insulating layer 380; and the second substrate 320 includes a support layer 340, an oxidation layer 350 arranged on a surface of the support layer 340 and a device layer 360 arranged on a surface of the oxidation layer 350.

The first substrate 310 and the second substrate 320 may be lightly-doped or heavily-doped Si substrates, or may be p-type or n-type doped substrate, wherein the dopant may be B, P, As or other dopant elements. In particular, the second substrate is used as a support substrate of a finally formed semiconductor substrate, which may be prepared by using materials within a more extensive range, even not limited to a semiconductor substrate.

The first insulating layer 330 and the second insulating layer 380 are independently made from any one of silicon oxide, silicon nitride and silicon oxynitride. The formation process may employ a chemical vapor deposition or thermal oxidation. In particular with respect to a monocrystalline silicon substrate, a silica insulating layer is formed by preferably using the thermal oxidization.

The device layer 360 may be formed by means of epitaxy. The epitaxy may be a homoepitaxy or an isoepitaxy, and the homoepitaxy is preferably used to achieve a higher crystal quality, for example, the device layer 330 having an epitaxy monocrystalline silicon on the surface of the first substrate made from a monocrystalline silicon. The oxidation layer 350 may be formed by means of ion injection, and is present in the second substrate 320 as a buried oxidation layer.

Further, as an optional step, upon this step, the method may further includes a step of forming an insulating layer on the surface of the device layer 360; and in the bonding step, the first substrate and the second substrate are bonded by using the insulating layer on the surface of the device layer 360 and the first insulating layer 330 as an intermediate layer.

As illustrated in FIG. 3B, with reference to step S22, the first substrate 310 and the second substrate 320 are bonded by using the device layer 360 and the first insulating layer 330 as an intermediate layer. The bonding herein may be common hydrophilic bonding or hydrophobic bonding, or may be plasma assistant hydrophilic bonding, preferably the hydrophilic bonding and the plasma assistant hydrophilic bonding.

With reference to step S23, the bonded substrate is annealed. By means of annealing, a covalent bond is formed at the bonding interface, which enhances the bonding force. The annealing temperature is higher than 900° C., the annealing duration is longer than 2 hours, and the annealing atmosphere is wet oxygen, dry oxygen, nitrogen or oxygen-argon mixture gas.

As illustrated in FIG. 3C, with reference to step S24, the second substrate 320 is thinned to remove the support layer 340. The step of thinning the first substrate 310 may employ a method of firstly grinding and then polishing. The grinding refers to coarsely grinding the first substrate 310 firstly and then finely grinding the first substrate 310. The first substrate is quickly thinned by means of coarse grinding, and damages caused by the grinding to the first substrate 310 are reduced by means of fine grinding. The polishing may employ chemical-mechanical polishing to conduct single-face polishing or double-face polishing, wherein the single-face polishing is preferably employed to prevent the insulating layer 330 on the second surface from being removed.

Further, if a chamfering is needed, before step S24, a chamfering process may be performed for the bonded substrate.

As illustrated in FIG. 3D, in step S25, a passivation layer 370 is formed on a surface of the second insulating layer 380 by epitaxy, wherein the second insulating layer 380 and the passivation layer 370 are configured to adjust warpage of the semiconductor substrate. In the subsequent corrosion step, the passivation layer 370 may not be corroded by the corrosion liquid, and the corrosion liquid may not corrode the second insulating layer 380, such that a low-warpage semiconductor substrate may be obtained. In this embodiment, the passivation layer 370 may be made from polycrystalline silicon.

In the present disclosure, the passivation layer may be formed by using, but not limited, to the following steps:

(1) defining a thickness of the passivation layer 370 to be formed according to the thicknesses of the second insulating layer 380 and the oxidation layer 350; (2) setting epitaxial furnace technique parameters; (3) testing the furnace to confirm the epitaxial effect and thickness parameter; (4) carrying out epitaxial growth.

As illustrated in FIG. 3E, in step S26, a corrosion step is performed for the substrate to remove the oxidation layer 350. In this step, the oxidation layer 350 is removed by means of corrosion to expose the device layer 360. When the substrate is corroded by using the corrosion liquid to remove the oxidation layer 350, although the corrosion liquid may sputter or flow to the bottom of the substrate, with the presence of the passivation layer 370 at the bottom of the substrate, the second insulating layer 380 would not be corroded by the corrosion liquid. In this way, a low-warpage semiconductor substrate is provided. If the oxidation layer 350 is silica, the corrosion liquid is preferably HF for corrosion.

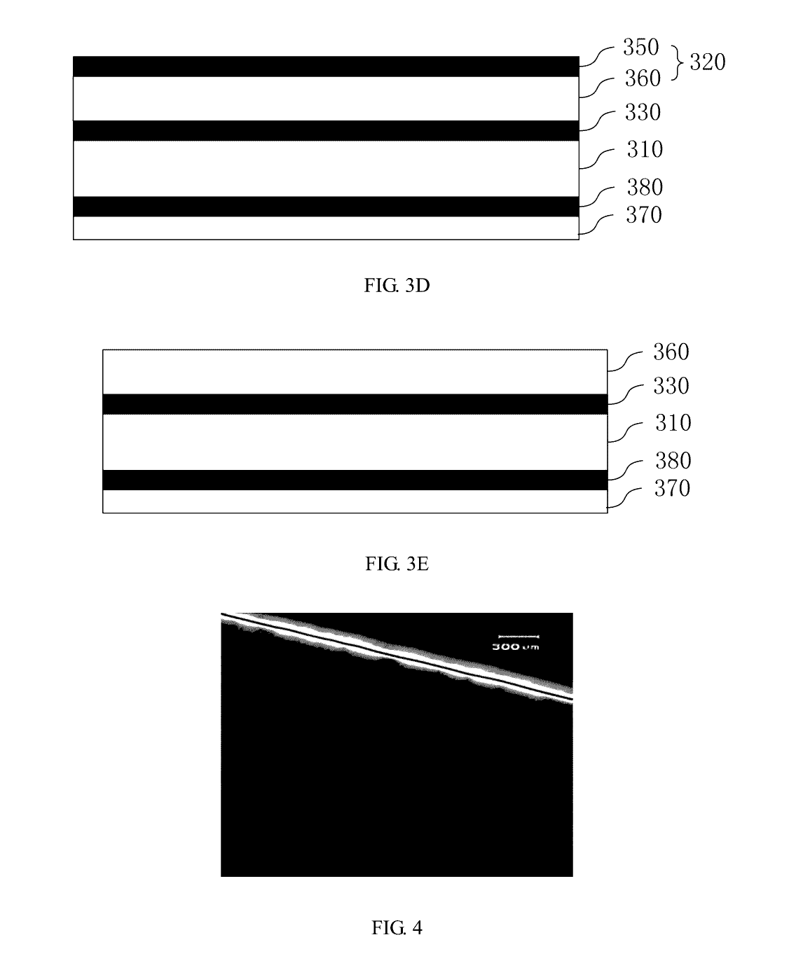

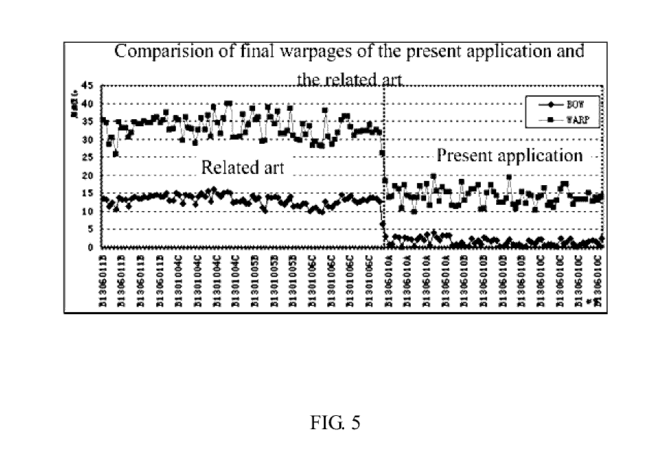

FIG. 4 is a transmission electron microscope of a semiconductor substrate prepared by using the method according to the present disclosure. As seen from FIG. 4, after the oxidation layer 350 is removed, compared with the related art, an inclination angle of the semiconductor substrate becomes smaller, which indicates that the warpage of the semiconductor substrate becomes smaller. FIG. 5 is a comparison of warpage of a semiconductor substrate prepared by using the method of the present disclosure, and warpage of a semiconductor substrate prepared by using a conventional method in the related art. As seen from FIG. 5, since the passivation layer 370 is formed on the surface of the second insulating layer 380 according to the present disclosure, the second insulating layer 380 is not corroded by the corrosion liquid. Therefore, the warpage of a semiconductor substrate prepared by the method of the present disclosure is smaller than that of a semiconductor substrate prepared by using a conventional method in the related art. In the present disclosure, the warpage of the substrate may be adjusted according to the thicknesses of the buried oxidation layer 350, the second insulating layer 380 and the passivation layer 370; when a low-warpage substrate is needed, the thicknesses of the buried oxidation layer 350, the second insulating layer 380 and the passivation layer 370 are made to be greater; otherwise, the thicknesses of the buried oxidation layer 350, the second insulating layer 380 and the passivation layer 370 are made smaller. In this way, the warpage of the substrate is adjusted by controlling the thicknesses of the buried oxidation layer 350, the second insulating layer 380 and the passivation layer 370.

The present disclosure further provides a low-warpage semiconductor substrate. As illustrated in FIG. 3E, the low-warpage semiconductor substrate includes: a support substrate 310, a first insulating layer 330, a second insulating layer 380, a device layer 360 and a passivation layer 370. The support substrate 310 includes a first surface and a second surface which are opposite to each other. The first insulating layer 330 is arranged on a first surface of the support substrate 310. The device layer 360 is arranged on a surface of the first insulating layer 330. The second insulating layer 380 is arranged on the second surface of the support substrate 310, the passivation layer 370 is arranged on a surface of the second insulating layer, and the second insulating layer and the passivation layer are configured to adjust the warpage of the semiconductor substrate. In this embodiment, the passivation layer 370 is made from polycrystalline silicon, the first insulating layer 330 and the second insulating layer 380 are independently made from any one of silicon oxide, silicon nitride and silicon oxynitride.

In this disclosure, the passivation layer may be made from polycrystalline silicon, and the first insulating layer and the second insulating layer are independently made from any one of silicon oxide, silicon nitride and silicon oxynitride.

Here, after the bonding step, the method may further include a step of annealing the bonded substrate. Upon the bonding step, the method may further include a step of thinning the second substrate to remove the support layer. Upon the thinning step, the method may further include a corrosion step to remove the oxidation layer. The thinning step employs one or both of mechanical grinding and chemical-mechanical polishing. Upon the bonding step, the method may further include a step of chamfering the second substrate and the first insulating layer.

Described above are preferred examples of the present disclosure. It should be noted that persons of ordinary skill in the art may derive other improvements or polishments without departing from the principles of the present disclosure. Such improvements and polishments shall be deemed as falling within the protection scope of the present disclosure.

What is claimed is:

1. A low-warpage semiconductor substrate, comprising:
a support substrate comprising a first surface and a second surface which are opposite to each other;
a first insulating layer, arranged on a first surface of the support substrate;
a device layer, arranged on a surface of the first insulating layer; and
a second insulating layer and a passivation layer, the second insulating layer being arranged on a second surface of the support substrate, the passivation layer being arranged on a surface of the second insulating layer, and the second insulating layer and the passivation layer being configured to adjust warpage of the semiconductor substrate.

2. The low-warpage semiconductor substrate according to claim 1, wherein the passivation layer comprises polycrystalline silicon, and the first insulating layer and the second insulating layer are independently made from one of silicon oxide, silicon nitride, and silicon oxynitride.

3. The low-warpage semiconductor substrate according to claim 1, wherein the first insulating layer comprises one of silicon oxide, silicon nitride, and silicon oxynitride.

4. The low-warpage semiconductor substrate according to claim 1, wherein the second insulating layer comprises one of silicon oxide, silicon nitride, and silicon oxynitride.

5. A method for preparing a low-warpage semiconductor substrate, comprising:
providing a first substrate and a second substrate, the first substrate comprising a first surface and a second surface which are opposite to each other, disposing a first insulating layer on the first surface, disposing a second insulating layer on the second surface, and the second substrate comprising a support layer, an oxidation layer arranged on a surface of the support layer, and a device layer arranged on a surface of the oxidation layer;
bonding the first substrate and the second substrate by using the device layer and the first insulating layer as an intermediate layer; and
forming a passivation layer on a surface of the second insulating layer by epitaxy, the second insulating layer and the passivation layer being configured to adjust warpage of the semiconductor substrate.

6. The method for preparing a low-warpage semiconductor substrate according to claim 5, further comprising annealing the bonded substrate after bonding the first substrate and the second substrate.

7. The method for preparing a low-warpage semiconductor substrate according to claim 5, further comprising thinning the second substrate to remove the support layer after bonding the first substrate and the second substrate.

8. The method for preparing a low-warpage semiconductor substrate according to claim 7, further comprising a corrosion step to remove the oxidation layer after the thinning step.

9. The method for preparing a low-warpage semiconductor substrate according to claim 7, wherein the thinning step employs one or both of mechanical grinding and chemical-mechanical polishing.

10. The method for preparing a low-warpage semiconductor substrate according to claim 5, further comprising chamfering the second substrate and the first insulating layer after bonding the first substrate and the second substrate.
